(19) United States
(12) Patent Application Publication
(10) Pub. No.: US 2011/0079267 A1
(43) Pub. Date: Apr. 7, 2011

(54) LENS SYSTEM WITH DIRECTIONAL RAY SPLITTER FOR CONCENTRATING SOLAR ENERGY

(75) Inventors: MARK A. RAYMOND, LITTLETON, CO (US); HOWARD G. LANGE, MOUNT PROSPECT, IL (US); SETH WEISS, CHERRY HILLS VILLAGE, CO (US)

(73) Assignee: GENIE LENS TECHNOLOGIES, LLC, ENGLEWOOD, CO (US)

(21) Appl. No.: 12/896,596

(22) Filed: Oct. 1, 2010

Related U.S. Application Data
(60) Provisional application No. 61/248,240, filed on Oct. 2, 2009.

(51) Int. Cl. H01L 31/052; F24J 2/08; F24J 2/38

(52) U.S. Cl. 136/246; 126/698; 126/573

(57) ABSTRACT

A concentration system or solar concentrator for supplying concentrated solar energy. The system includes a lens array with linear lenses focusing light received on an outer surface onto a number of focal point or focused lines of light. The system includes a light wafer with a substantially planar body formed of a thickness of a light transmissive material. The body includes a top surface facing the lens array and receiving the focused light from at least one the linear lens and further includes a bottom surface opposite the top surface. The light wafer includes a ray splitter, in the form of a triangular air gap, paired to each linear lens at or near a focal point of the paired lens to direct the received focused light into the body or towards edges or sides of the body where a solar collector such as a thermal or photovoltaic collector is positioned.

### CROSS-REFERENCE TO RELATED APPLICATIONS

This application claims the benefit of U.S. Provisional Application No. 61/248,240 filed Oct. 2, 2009, which is incorporated herein by reference in its entirety.

### BACKGROUND OF THE INVENTION

1. Field of the Invention

The present invention relates, in general, to concentrators for use in the solar power industry, and, more particularly, to systems, devices and methods for more effectively concentrating solar energy (or, more simply, for concentrating sunlight) using an improved tracking concentrator such as a fiber optic wafer concentrator adapted for effective tracking of the Sun.

2. Relevant Background

In general, concentrated solar power systems use lenses or mirrors to focus a large area of sunlight onto a small area. Electrical power is produced when the concentrated light is directed onto photovoltaic surfaces or when the concentrated light is used to heat a transfer fluid for a conventional power plant (e.g., to run a turbine with steam).

With regard to the latter example, thermal concentrators have been around for many years, with concentrated solar thermal (CST) being used to produce renewable heat or electricity (which may be labeled thermoelectricity as it is usually generated via steam generation). A wide range of concentrating technologies exists with a parabolic trough being a popular choice for use in many CST systems. A parabolic trough includes a linear parabolic reflector that concentrates light onto a receiver that is positioned along the reflector's focal line. The receiver is typically a pipe or tube (i.e., is an absorber tube) positioned directly above the middle of the parabolic reflector (or mirrored surface that may be a coating of silver, polished aluminum, or the like). The pipe or tube is filled with a working or transfer fluid. The reflector is operated to attempt to accurately track the Sun's movements during daylight hours by tracking along a single axis. In some cases, the working fluid is an oil, a molten salt, or other material that is heated to high temperatures (300 to 700° F.) as it flows through the receiver, and fluid is then used as a heat source for a power generation system (e.g., to heat water to create steam that is used to turn a turbine generator or the like).

There is a strong desire to expand the use of renewable energy sources such as thermal concentrators. As discussed above, CST systems generally track the Sun east to west from the morning to evening hours, and this is done with a complex tracking system that tilts a linear parabolic concentrator or reflector, which may be may several hundred meters long and up to as much as ten or meters across. Generally, the lines or solar filed piping/absorber tubing of these systems are linked together to heat water and in turn generate steam to drive a turbine generator to provide electricity. The parabolic concentrators are generally made of glass with a mirror backing material and include a sturdy framing system that is positioned or controlled with a computerized one axis tracking system. The parabolic concentrators are generally focused to heat an absorber tube made of tempered glass and containing water, oil, or the like that is pumped through the tube (which is generally 5 to 10-inches in diameter) at the correct rate depending upon the length of the concentrator and corresponding to the overall size of the system.

While being desirable for using a renewable power source, CST systems, such as those that utilize parabolic concentrators with single-axis tracking capabilities, have not been widely adopted. One drawback with CST systems is that they tend to be quite inefficient, and this lack of efficiency is especially acute during months where the incidence angle of the sun is the furthest from perpendicular. Collecting efficiencies due to the skewed focus of the troughs can drop to under fifty percent in these conditions. In addition, the absorber tube or pipe carrying the heated fluid may be relatively large in diameter and is located directly in front of the concentrator (i.e., in the trough of the parabolic reflector or the like), which shadows the overall collection device and decreases efficiency further. Efficiencies of CST systems are a concern as the overall efficiencies from collector to grid may be as low as about fifteen percent. Hence, there is a need to enhance efficiencies at each step of the process including collection and thermal efficiencies proximate or within the collector assembly.

Additional drawbacks of conventional parabolic concentrators include expense of manufacturing, lack of efficiency during many months of the year (e.g., due to non ideal azimuth angles), and fragility of the parabolic trough materials (e.g., which may lead to damage under normal operating conditions such as due to weather conditions including hail, strong winds, and the like). In addition, parabolic reflectors or concentrators tend to be quite dangerous to work around during sunlight hours as they produce concentrated beams of sunlight that can cause severe burns and even blindness and as many of the parts of the system are at very high operating temperatures.

Further, one of the larger drawbacks is the need to maintain the reflector and absorber tubing outer surfaces in a very clean state to maintain light collection and thermal efficiencies in desired ranges. As a result, a problem with parabolic concentrators is the difficulty of cleaning the systems including the large usage of cleaning chemicals and water. Large systems require constant cleaning and rinsing, adding costs and, over time, contaminating soil underneath the reflectors. In desert conditions where many CST systems are located, it is particularly expensive and difficult to provide water for cleaning these units. Most arrays are cleaned by crews on an ongoing basis or seven days a week, which increases the maintenance or operating costs associated with generation of electricity with CST systems.

Hence, there remains a need for a more modern, scalable concentrator system. Preferably, such a concentrator system would be easier to clean including using less water and chemicals. The system may be cheaper to manufacture and less dangerous to operate and maintain (and more durable such as being less likely to be damaged by hail or the like). Further, the concentrator system may be more efficient (with a lower cost per watt of generated electricity). Still further, the concentrator system may be useful for heating a variety of transfer or working fluids including heating oil, glycol, air, or other liquids and also have the ability to function as a photovoltaic concentrator at the same time or independently from heating a working or transfer fluid. The concentrator system preferably would be designed for use with strictly photovoltaic (PV) concentrator systems as well as for use with CST systems and systems combining thermal and PV devices (e.g., collectors or receivers (or sheets) that contain both PV elements and thermal concentration elements).

### SUMMARY OF THE INVENTION

The present invention addresses the above and other problems by providing a concentrator or concentration system for a solar energy system (e.g., a concentrated solar power (CSP) system with a PV, thermal, combination PV and thermal, or other receiver/collector). The concentration system described herein is a very inexpensive solar concentration system that uses a lens assembly to focus received sunlight into a light wafer configured to have an assembly or plurality of angular “ray splitters.” In some cases, each lens of the lens assembly focuses on (or has its focal point on or approximate to) one of the ray splitters. The light wafer of the concentration system may be a planar sheet of glass, plastic, ceramic, or the like that acts as a light pipe for the concentrated or focused sunlight after it is split or redirected by the ray splitters. In other words, the focused light entering the light wafer is directed in different directions by the ray splitters and then is retained within the sheet of glass, plastic (or other polymer), or ceramic using total internal reflection (TIR), which sends a large portion of the sunlight to the edges or sides (or ends) of the planar light wafer to a thermal, PV, or other collector/receiver of the solar energy system (e.g., a concentrated solar power (CSP) system).

The concentration or focus of the light with the lens assembly may be done with very small cylinder or elliptical lenses configured to have short focal lengths or, in some cases, with large curved or flat Fresnel lenses that may be linear and point lenses. By including one or more tracking devices in the concentration system, tracing or tracking of the Sun's movement with the ray splitter assembly may be one axis (i.e., east to west) or be performed along two axes to attempt to provide a more perfect or preferred focus of the concentrated light onto the light wafer (and its ray splitters). The receiving wafer (e.g., planar sheet or light wafer) may have a variety of body shapes such as be round, oblique, polygonal, square, or rectangular.

The concentration system may be described briefly as a lens system that may be linear, round, square, or rectangular (e.g., nearly any flat shape) accompanied with a flat or planar sheet of glass, plastic, ceramic, or other material (useful for providing a planar light pipe). The planar sheet or light wafer utilizes or includes small angular structures (i.e., a ray splitter assembly) to split the rays or send them in a particular direction to achieve a nearly unlimited concentration ratio. In some embodiments, the angular structures are provided as elongated, parallel grooves on a back surface of the light wafer, with each groove having a triangular cross section (with “back” referring to the side of the wafer opposite the lenses or opposite the light receiving surface of the wafer). When the wafer is then viewed as a cross section, the “inside” of the wafer or sheet appears to have a number of side-by-side triangular sidewall features or indentations that are useful for splitting or redirecting the focused light toward one or two edges of the light wafer, and a PV or thermal collector may be positioned at these locations or wafer sides/edges to receive the highly concentrated solar energy.

The concentration system described is extremely inexpensive and is a very efficient solar energy collection and concentration device as the inventors believe it will allow several thousand suns of concentration and provide a system in which multiple units may readily be linked together (in a CSP system with two or more concentrators or concentration systems as described herein).

The concentrator or concentration system is particularly inexpensive since the concentration or light wafer may be implemented using a conventional sheet of plastic or glass (e.g., from less than 0.001 inches to several inches thick) that is adapted or manufactured to include the ray splitters. For example, many devices may use sheets of glass, plastic, or ceramic in the 0.125-inch to 0.25-inch range for the light or concentrator wafers (or sheets, panels, or the like). While in most of the versions the concentrator sheets, wafers, or panels would be flat, some embodiments may provide concentrators that have a slight inward or outward curve to the sheets with the ray splitters (e.g., the embodiments may be thought of as substantially planar which includes large radius curved surfaces to maintain TIR more easily and support accurate focusing of the lens assembly on the ray splitters).

The energy receivers or collectors would typically be positioned outside of the glass or substrate at the edges of the material of the light wafers or concentrator sheets. In other embodiments, the solar collectors (PV devices, thermal absorber tubes, a PV/thermal combination apparatus, or the like) may be positioned within the light wafers themselves such as in the form of tubes or cylinders holding liquid, air, salt, or the like. In other CSP systems using the concentrator systems of the invention, PV devices are assembled within the wafers. For example, but not as a limitation, the wafers may be configured with linear pieces/arrays of or spots of PV material absorbing light along the edges/sides of the wafers or anywhere on the wafer or sheet of glass, plastic, or other light transmissive material (e.g., absorbing any rays lost to TIR on the planar surfaces of the wafers).

More particularly, a concentration system or solar concentrator is provided for supplying concentrated solar energy (e.g., to a working/transfer fluid for use in thermal storage or a power generation plant or to a PV collector or a combination thereof). The system includes a lens array with at least one linear lens extending a length of the lens array and focusing light received on an outer surface onto a focal point. The system further includes a light wafer with a substantially planar body formed of a thickness of a light transmissive material. The body includes a top surface facing the lens array and receiving the focused light from at least one the linear lens and further includes a bottom surface opposite the top surface. Significantly, the light wafer includes at least one ray splitter directing at least a portion of the received focused light into the body, whereby at least a portion of the directed light from the ray splitter is trapped in the body by total internal reflection. Hence, in this description, the light wafer itself may be called a “ray splitter” that accompanies a lens system or lens array (to provide an improved solar concentrator).

In some embodiments, two to ten lenses are provided in the lens array and a like number of ray splitters are provided in the light wafer (or concentration panel/sheet) for each of the lenses to focus upon in the material of the wafer. Each of these ray splitters is positioned proximate to the focal point of one of the linear lenses. In the system, each ray splitter may be provided by a linear groove extending along a length of the body on the bottom surface so as to provide an air gap defined in the body opposite the top surface.

Specifically, the linear groove may be defined by a pair of sidewalls each extending at an angle from the bottom surface to meet at an apex, whereby the air gap has a triangular cross sectional shape. The angle may be selected from the range of 37 to 55 degrees such as an angle of about 45 to about 48 degrees. In such systems, the portion of the directed light striking each ray splitter is split or divided into two sets of rays with a first set directed toward a first edge of the light wafer body and a second set directed toward a second edge of the light wafer body. In the system, a first collector may be positioned at the first edge to receive at least a portion of the first set of rays and a second collector may be positioned at the second edge to receive at least a portion of the second set of rays. The first and second collectors may each be a thermal collector, a photovoltaic collector, or a combination thermal and photovoltaic collector. The system may be configured to provide a concentration ratio of at least about 20 Suns.

In some embodiments of the system, the light wafer further includes a mirror element with a reflective surface facing the bottom surface to reflect a portion of the focused light escaping the body back into the body. In the same or other embodiments, the system may also include at least one photovoltaic collector element proximate the bottom surface to receive a portion of the focused light escaping the body. The lenses may each take many forms to focus the light into the light wafer and on the ray splitters such as a planar or arched, linear Fresnel lens.

Sun position tracking may be provided to maintain proper focusing upon the light wafer by the lenses. For example, the concentrator assembly may include an array positioning mechanism providing two-axis tracking of the lens array including tracking a position of the Sun during daytime hours and periodically adjusting the lens array height based on the Sun's azimuth to match a focal length of the linear lenses to the array height.

### BRIEF DESCRIPTION OF THE DRAWINGS

FIG. 1 shows a functional schematic view of an embodiment of a concentrated solar power (CSP) system of the present invention showing the combination of an adjustable position (or height) lens array/assembly and light wafer (or concentrator sheet/panel), which includes a plurality of ray splitters that redirect the focused light to retain the light in the wafer for use by a collector (or absorber tube, in this case);

FIG. 2 illustrates a sectional end view of a concentration system or assembly (such as may be used in the CSP system of FIG. 1) showing the focusing of an array of linear lenses onto a concentration panel (e.g. a sheet of plastic, glass, ceramic, or the like) that includes a back surface with a plurality of ray splitters or beam redirecting surfaces;

FIG. 3 illustrates the concentration system of FIG. 2 with an overlay showing a ray tracing for the system indicating that TIR traps most of the light focused onto ray splitters of the concentration panel by the lenses of the lens array;

FIG. 4 is a close up or enlarged view of one ray splitter of the concentration assembly of FIG. 3;

FIG. 5 shows a particular collector (e.g., an absorber tube for containing working/transfer fluid) for use in the concentration system of FIGS. 2-4;

FIGS. 6 and 7 illustrate ray tracing plots for a portion of concentrator assembly with a fixed array height but light at two differing seasonal Sun positions;

FIG. 8 is a plot indicating a fraction of light reflected versus incidence angles in a light wafer illustrating aspects of total internal reflection utilized in the present invention;

FIG. 9 is a partial sectional view of an array or assembly of light wafers or concentration panels arranged in a stacked but offset manner so as to stagger the ray splitter structures in each consecutive layer such that each layer is effective for capturing sunlight striking the array at differing entrant or incidence angles;

FIG. 10 is a partial perspective and schematic view of another embodiment of a concentration system of the present invention showing use of a lens array with non-linear lenses (such as circular Fresnel lenses or the like) that provide focus points or spots into a concentration panel with a plurality of non-linear or spot-type ray splitters (e.g., cone or cone-like shapes provided as recesses/dimples in the back or rear surface of the concentration panel); and

FIG. 11 is a top view of the concentration system of FIG. 10 showing the full lens array and also showing one arrangement for a collector or collection assembly about the edges of the concentration panel to collect the light directed toward all edges of the panel's body or sheet.

### DETAILED DESCRIPTION OF THE PREFERRED EMBODIMENTS

The following description begins with specific examples or implementations of sunlight or solar energy concentration assemblies or systems that may be used a concentrated solar power (CSP) system. These discussions include references to ray tracings performed on some particular designs for lens, wafer, and ray splitter combinations to concentrate and deliver sunlight to a collector/receiver (e.g., PV collector, thermal collector, or the like) at the edge of the wafer. Prior to discussing these specific embodiments, though, it may be useful to more generally discuss a number of features or aspects of these concentration systems and the advantages they provide over existing concentrators.

One advantage of the ray splitting-based concentration system is a significant reduced manufacturing and maintenance cost due to the use of readily available materials that are easily manufactured (e.g., sheets of glass that may be formed or cut to have grooves/indentations to provide a plurality of ray splitters). Further, though, a large benefit is the enormous concentration ratios that are possible with the concentration systems described herein. While, as the distance increases, eventually there may be a limit to the concentration ratio as some rays continue to escape around the splitters, several thousand Suns' concentration ratios are possible at the edges of the concentration or light wafers, panels, or sheets. Surface areas of over several hundred meters of incoming energy can be focused into a line at the edge of the concentration panel or light wafer that is at or about the thickness of the wafer or panel (e.g., 0.125 to 0.25 inches or the like).

Since the concentration ratios can be so large, it is possible to have the edges of the light wafer equipped with high-pressure capable collectors that superheat air or other fluids (flowing in the absorber tube or collector) to drive turbines or otherwise make use of the concentrated solar energy. Since it is necessary to have temperatures of over 1,000° C. to accomplish the superheated air implementation, prior collectors did not have the ability to superheat air as required. In contrast, it is believed that with the described concentration system and CSP systems using such concentrator techniques several thousand degrees Celsius temperatures are easy to achieve. Concentrator systems that run turbines on hot air are extremely efficient, posting over seventy percent efficiency in some cases as compared to under thirty percent with typical water systems, but, of course, the concentration systems shown and described may be used with water and other fluids in a thermal collector or absorber tube). Air systems, though, present fewer problems and can be scaled more efficiently as there is no need to use pump stations, no issues with freezing collector fluids, and, of course, no need for water, all of which make the described concentration systems well-suited for (but clearly not limited to use with) air-based thermal CSP systems. The collectors can be located at the edge of the glass or other material light or concentrator wafers/panels and can be insulated and pressure reinforced on all sides except for the ray entrance side of the collector where the rays exit the wafer/panel and pass into the collector.

Those skilled in the art will readily recognize that very high efficiency CSP systems are possible and practical with the concentration systems, e.g., because of the extraordinarily high concentration ratios and other operating characteristics of the systems. The concentration systems have a desirable simplicity of design and may be fabricated using cheap and readily available materials (rather than exotic metals, chemical compounds, and the like). The concentration system is also quite safe, scalable, and efficient. Another big advantage of the described concentration systems are their ease of cleaning, which may be completely automated.

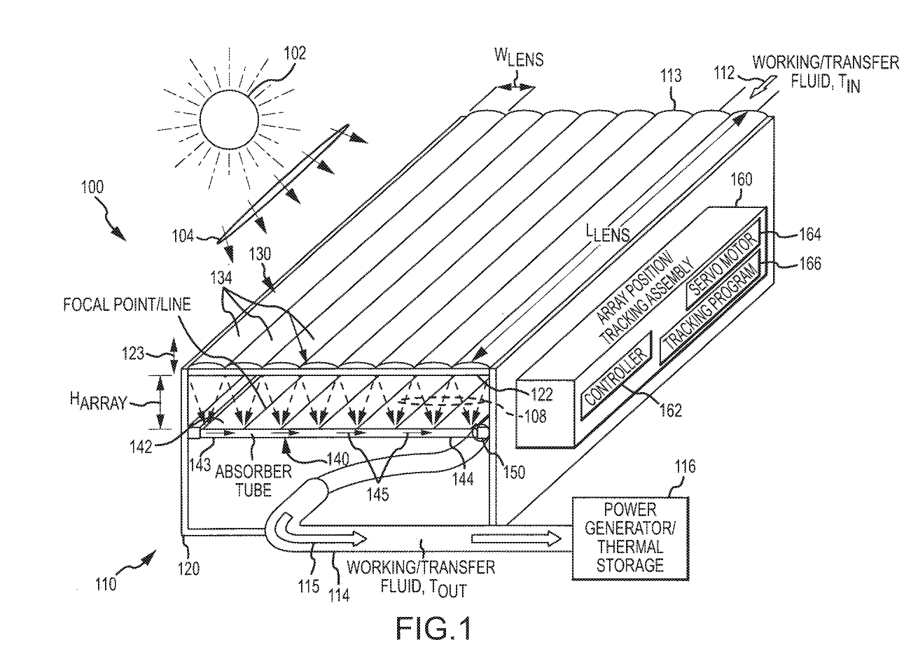

The present invention is generally directed toward new concentrators or concentration systems for more effectively collecting solar energy throughout the day and over two or more seasons. FIG. 1 illustrates schematically (or in functional block form) a concentrated solar power (CSP) system 100 of one embodiment. As shown, the CSP system 100 includes a concentration system or assembly 110 that combines a lens array 130 with a light wafer or concentration panel/sheet 140 (with ray splitters (not shown in FIG. 1)). The concentrator assembly 110 typically uses tracking and/or be configured to have the lens array 130 be adjustable to adjust for daily and/or seasonal changes in the position of the Sun 102.

Briefly, the CSP system 100 includes the concentration system 110 that includes a housing 120 in which a lens frame or support 122 is provided near an upper opening. The housing 120 also supports a light wafer or concentration panel/sheet 140. The light wafer 140 is typically planar or substantially planar and rigidly mounted in the housing 120 with a light receiving or first surface 142 (e.g., a set of focal points or lines for the lenses 134 of array 130 are presented on an upper surface 142 of light wafer) and with a second surface 143 facing away from the lenses 134 (e.g., to provide the ray splitters opposite or directed inward toward the first surface 142).

The concentration system 110 includes the lens array 130 that is made up of a plurality of linear lenses 134 (e.g., linear Fresnel lenses or the like) each with a width, W_{Lens}, and a length, L_{Lens} (e.g., with a length, L_{Lens}, that is much greater than the width, W_{Lens}). The elongated (and generally planar) lenses 134 are supported in the frame 122 with an upper or receiving surface facing outward from housing 120.

As shown, the concentration system 110 is positioned to receive solar energy or sunlight from the Sun 102. The lenses 134 of the lens array 130 are arranged to focus light 108 onto the upper or first surface 142 of the concentration panel or light wafer 140. To this end, the array 130 may be moved 123 to change its relative distance or height, H_{Array}, from the wafer 140 and receiving or first surface 142. In some preferred embodiments, the distance, H_{Array}, is chosen and the lenses 134 are each configured to focus on the focal point/line, which is over or proximate a linear ray splitter (not shown in FIG. 1) provided on surface 143. The light wafer or concentration panel 140 is typically formed from a sheets of plastic, glass, ceramic, or other light transmissive material that is arranged in the housing 120 to trap (through the use of the ray splitters) and transport (via total internal reflection (TIR), without significant losses, the light 108 from the first surface 142 to at least one edge or side 144 as shown with arrows 145. The edge/side 144 is shown to abut or be near to collector or absorbing tube 150 carrying working/transfer fluid (e.g., air or the like).

The concentrator or concentration system 110 further includes an array position and tracking assembly 160 that is adapted to alter the position of the lens array 130 to track the position of the Sun 102 relative to the light receiving surface of the lenses 134. For example, the assembly 160 may include a controller (e.g., an electronic or computer device with a processor running one or more sets of code to perform particular functions) 162 that selectively issues control signals to a servo motor or similar device 164 to pivot the array 130 on an axis to provide intraday tracking. Further, the servo motor 164 preferably is able to set and change 123 the distance or height, H_{Array}, above the wafer 140 and receiving surface 142 such that the lenses 134 focus the light 108 generally into the wafers 140 onto a ray splitter.

The adjustment of the separating distance, H_{Array}, between the lenses 134 and the receiving surface 142 is discussed in more detail below, and this feature is provided to adjust the array 134 to account for seasonal changes in the position of the Sun 102 (e.g., the angle of received sunlight 104 that changes over the course of a year). The operation of the controller 162 may include running one or more tracking programs 166 that may define height, H_{Array}, such as based on a calendar and geographical location of the concentrator or concentration system 110, and that may provide input for daily tracking operations for concentrator 110.

The light 108 then travels 145 within the wafer 140 to be output at ends/edges 144 into the tube 150. In some cases, the ray splitters (discussed below) may only direct light 145 one direction as shown while in many embodiments the light 108 would be directed to travel to both edges/sides of the wafer 140 and a second collector would be positioned at the edge/side opposite edge/side 144. A working or transfer fluid 113 is fed into the tube 150 at an inlet 112 to the concentration system 110 at a first, lower temperature, T_{In}. Along the length of the absorber tube 150 between the inlet 112 and outlet 114, the fluid is heated by focused/concentrated (and combined) light 108/145 so that the fluid 115 is output at the outlet 114 at a second, much higher temperate, T_{Out}. The tube 150 may be formed with substantially transparent sidewalls (of glass, plastic, or ceramic materials) and support the ends 144 to direct the light 108/145 through the sidewalls. The heated fluid 115 (e.g., superheated air or other material/fluid useful in thermal CSP systems) may then be transferred to a power generator or thermal storage 116 where the collected solar energy may be utilized such as by creating steam to drive a steam generator, to heat materials for thermal storage, and so on as is well known in the power industry. One concentrator 110 is shown in CSP system 100 but, of course, a typical CPS system 100 will include additional concentrators 110 providing a system or field of solar piping 114 that would be combined at inlet and outlet manifolds to the power generator/thermal storage 116.

In one embodiment, the lenses 134 are linear Fresnel lenses. Such linear Fresnel lenses 134 may be curved or flat and made of a variety of transparent materials (or at least translucent to substantially transparent materials) such as a glass, a plastic, a ceramic, or a combination thereof. Linear Fresnel lenses 134 may be extruded at high rates of speed and may be up to 8 feet or more wide, W_{Lens}, and nearly infinitely long, L_{Lens}, (with 20 to 50 feet or more in length being common for many arrays 130). The lenses 134 are assembled in frame(s) 122 and mounted next to each other (width wise) to provide each array 130. Several lenses 134 may be mounted across the frame 122 to provide an array 130 having a width of 50 feet or more. Focal lengths of the lenses are usually around 1.5 times their width, W_{Lens}, but this may vary depending upon the lens design. In some cases of concentration system 110, therefore, the height, H_{Array}, may be adjusted 123 by array position assembly 160 to be about 1.5 times the width, W_{Lens}. The design of the arrays 130 allows the collection system 110 to remain low profile, yet provide very large concentration ratios.

Linear Fresnel lenses can be made from extrusion, casting into the polymer, or applying ultraviolet (UV) beams or E-Beam (energy cured polymers) over a sheet or roll of material (e.g., a plastic). For commercial and industrial concentrators, the width of the lenses would normally be selected from a range of about 8 inches to about 8 feet or more. Most industrial extrusion lines have widths of about 4 feet wide at their maximum; however, there are extrusion lines (and devices) that are over 8 feet wide such that these or other practical limitations may set the lens width of the lenses in each lens array. The Fresnel lenses can be made from thicknesses of about 0.03125 inches to about 0.25 inches or more depending upon the application. In some cases, the Fresnel lenses can be made in sections and pieced together in both (or either) length and width, forming widths of over 4 meters and nearly any desired lengths.

Fresnel lenses for the lens arrays of the concentrators can be made, in some exemplary processes, at a rate of over 20 feet per minute in extrusion and over 100 feet per minute in energy cured casting. As a result, it will be appreciated that the production of the Fresnel lenses may be very fast and is readily scalable. Materials of choice for the Fresnel lenses include, but are not limited to PMMA (or poly(methyl methacrylate)), acrylic, fluoropolymer, polycarbonate, and glass. Selection of the width of the lenses corresponds in most cases to the focal length of the lenses (and desired distance to the receiving/leading edge of the light wafers of the collector/concentrator), and, therefore, in an industrial concentrator the height of the overall device. Generally speaking, to reduce Fresnel reflections, focal lengths are normally about one to two times the width of the Fresnel lens.

Fresnel lenses used for these concentrators can be curved Fresnel lenses or flat Fresnel lenses. Typically, the lenses for these concentrators are positioned within the lens array and supporting frame with the structures of the Fresnel lens facing down or away from the Sun (e.g., FIG. 1 shows, for ease of illustration, the curved and structured part of the lenses 134 up but this arrangement may be reversed in some embodiments of the concentration system 110). The Fresnel lenses made with the structures down provide a smooth top, which makes the lenses easier to clean, whether they are flat Fresnel lenses or curved Fresnel lenses.

The decision as to whether use curved Fresnel lenses or a flat Fresnel lenses may be based upon the application, costs, and other factors. An advantage to using curved Fresnel lenses versus flat Fresnel is their ability to more readily focus larger angles of incidence making them a more forgiving lens for focusing. The facets in the Fresnel lenses can be made in various sizes, from as little as 1/1000-inch to over ⅛-inch with from about 1,000 facets per inch to less than 6. On the average, an extruded lens will have between 50 and 500 facets per inch, and most energy-cured lenses will be much finer, e.g., utilizing between 100 and about 1,000 facets per inch. Normally, energy-cured lenses are made on thinner films, and they may then be laminated to thicker PMMA or acrylics for structural integrity.

For the concentration systems described herein such as system 110, multiple lenses 134 are lined up in a frame 122, and their energy 108 is joined together by light wafer or concentration panel 140. This allows the Fresnel lens array 130 to have a low profile (smaller width, W_{Lens}, and, therefore, shorter focal lengths (i.e., H_{Array} in preferred arrangements of concentrator 110) creating a lower profile) yet combine their energy together for a higher concentration ratio.

In some cases, the light wafer 140 is a sheet of glass, ceramic, or plastic (e.g., one preferred material is low-iron glass) of various thicknesses and sizes. The wafer 140 behaves much like commonly used fiber optic cable. Light enters through the surface 142, is split/deflected by a ray splitter provided on surface 143, and the light 145 then bounces around the inside of the light wafer (or its planar body) 140, which results in loss of very little energy and the received/focused light 108 from lenses 134 exits out edge/side 144. As shown in later figures, each lens 134 may be paired with at least one ray splitter. The wafer 140 typically is planar but may be bent to aim its end or edge 144 at a target, which in this case is a cylinder or tube 150 (while some embodiments may target a flat collector such as a collector or receiver with PV material or the like). Bends in the wafer 140 (e.g., in the sheet of glass or plastic used to form concentration panel 140) preferably are gradual so as to prevent the rays from leaking or escaping (or limiting such losses) by providing light ray bounces that exceed +/−42 degrees (e.g., a critical angle of 42 degrees with the angle of incidence being defined as the angle between the surface normal and the striking ray).

The Fresnel lens array 130 focuses light 108 down onto the first or receiving surface 142 of the light wafer or concentration panel 140, which is supported in housing 120. The focused or concentrated light 108 then travels as shown at 145 through the wafer 140 to the collector hub and cylinder collector 150 (exits second or outlet end 144 of wafer 140). In other words, the lenses 134 focus into the side 142 of the glass or plastic sheets 140, and light 108 travels through the “wafer” using total internal reflection (TIR) entering the wafer, being trapped through the use of ray splitters or ray deflectors, and remaining within the limits of TIR (e.g., about +/−42 degrees) as they bounce off the sidewalls/surfaces. The glass or plastic wafer may be from less than 1/32″ to over several inches thick.

The incoming rays 108, to be used as rays 145 by collector 150, must remain parallel to the entrant point at the side 144 of the glass or plastic (or other material) wafer 140 within the necessary +/−42 degrees parallel with the wafer sides, even in the bends of the glass, plastic, or ceramic wafer 140. Since the rays 108 travel through the glass, plastic, or ceramic wafer 140, it is preferred that care is taken in the design/installation of wafers 140 to not bend the wafer 140 radically so as to successfully contain/retain the rays 108 in the wafers 140 between surface 142 and side 144. Briefly, the wafer 140 is planar or bent gradually (substantially planer or the like) to provide a light path for light 108 as shown at 145 from the lenses 134 toward the collector 150 and its contained working fluid 113, 115.

The CSP system 100 may use the concentration system 110 to heat a wide variety of working/transfer fluids. For example, the fluid 113, 115 may be a glycol, water, and/or nearly any liquid material or a gas such as air to provide solar energy with heated fluid 115 to the power generator/thermal storage 116 (i.e., any device that may utilize energy in fluid 115). In other embodiments, not shown in FIG. 1 but part of this description, the concentrator 110 may be configured for use as a PV concentrator or a combination of PV and thermal concentrator such as by replacing all or portions of the absorber tube 150 with PV devices such as solar cells or panels or the like. In some cases, the PV materials/devices may be on surface 143 or at ends/edges 144.

As shown in FIG. 1 of the CSP system 100, the collector or absorber tube 150 may be filled with glycol, oil, liquid salt, or any number of liquids/solutions. In one case, the CSP system 100 is configured as a waterless, high-efficiency thermal system. Particularly, the collector system with absorber tube 150 may be a closed loop system with the oil or other transfer fluid 115 filling the collector pipe 150 and being circulated (via pumps or the like not shown) into a coil in a salt tank in the power generator/thermal storage 116. The salt is heated by the fluid 115 and, in turn, heats a hydrogen unit for a heat exchanger driving a Sterling engine (e.g., closed-loop hydrogen process). In other cases, the collector 150 may be configured to wrap around a heating unit in the generator/storage 116 to directly heat the hydrogen (or other material) driving a Sterling engine and heat exchanger. Part of the energy 108 may be collected concurrently (or in place of fluid 115) in some of wafers or the like in a PV application.

The CSP system 100 may be operated as a one-axis system without tracking as to seasons. However, such a system 100 would have some issues or nuances. The one-axis system 100 would be configured with array position/tracking assembly 160 to track much like a Sun trough, e.g., running north and south in length and tilting east in the morning and tracking the Sun directly overhead to west in the evening. The main issue is the seasonal azimuth of the Sun. Changes in seasonal azimuth in general prohibit perfectly aligned rays from being properly directed onto a ray splitter of the wafer 140. Much of this is a result of the focal length changes in the linear lenses 134 being either too long or too short, therefore missing a ray splitter or a desired portion of a ray splitter of the wafer 140.

To address this issued, the lenses 134 may have a second modified “axis” by configuring the concentrator assembly 110 to have the ability (via array position/tracking assembly 160) to raise slightly or lower slightly (123) with the azimuth of the Sun 102, thereby adjusting the focal lengths of the lenses 134 slightly to accommodate the seasonal azimuth helping to eliminate over and under focus (e.g., vary the array height, H_{Array}, a small amount over the year to account for seasonal movement of the Sun 102). By having the ability to lower or raise 123, the lenses 134 of array 130 can be positioned to received sunlight 104 and properly focus the light 108 onto ray splitters in wafer 140 as the focal length decreases or increases.

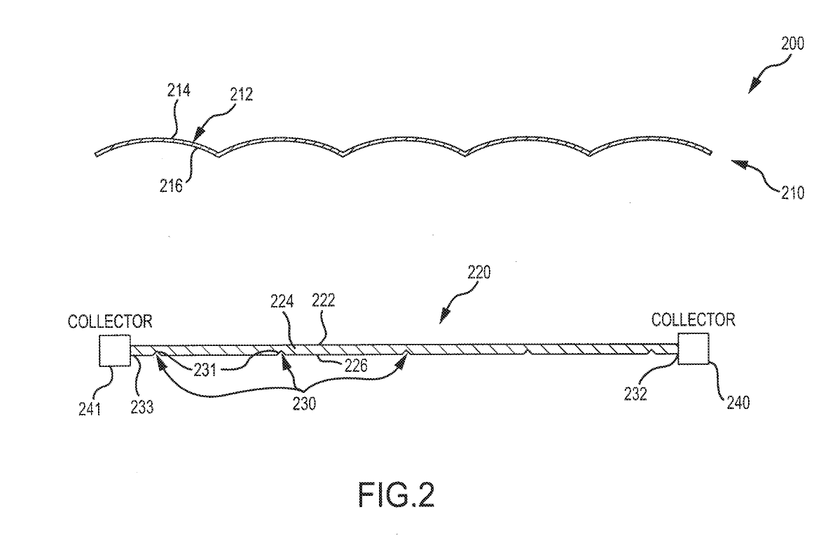

FIG. 2 illustrates a sectional end view of an embodiment of a concentration assembly or system 200 such as may be used in the CSP system 100 of FIG. 1. As shown, the system 200 includes a lens array 210 made up of five, side-by-side (with their longitudinal axes parallel), linear lenses 212. Each lens 212 may be a linear, arched Fresnel lens or another lens type with a first or receiving surface 214 facing outward (toward the Sun) from the system 200 and a second or focusing surface 216. The facets of the Fresnel lens 212 may be on either side with FIG. 2 showing the facets on inner or second surface 216. Of course, five is not a limiting number and one, two, or more lenses 212 may be included in array 210.

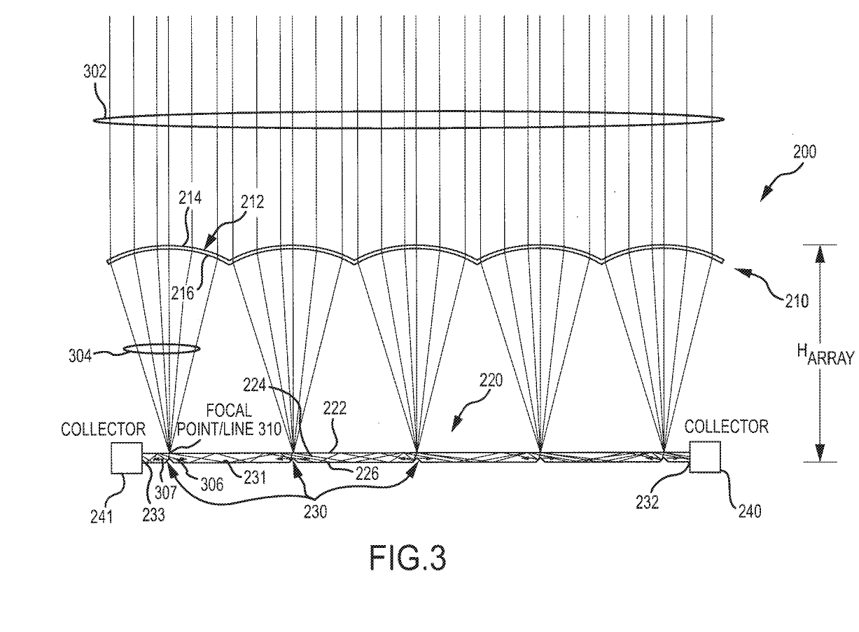

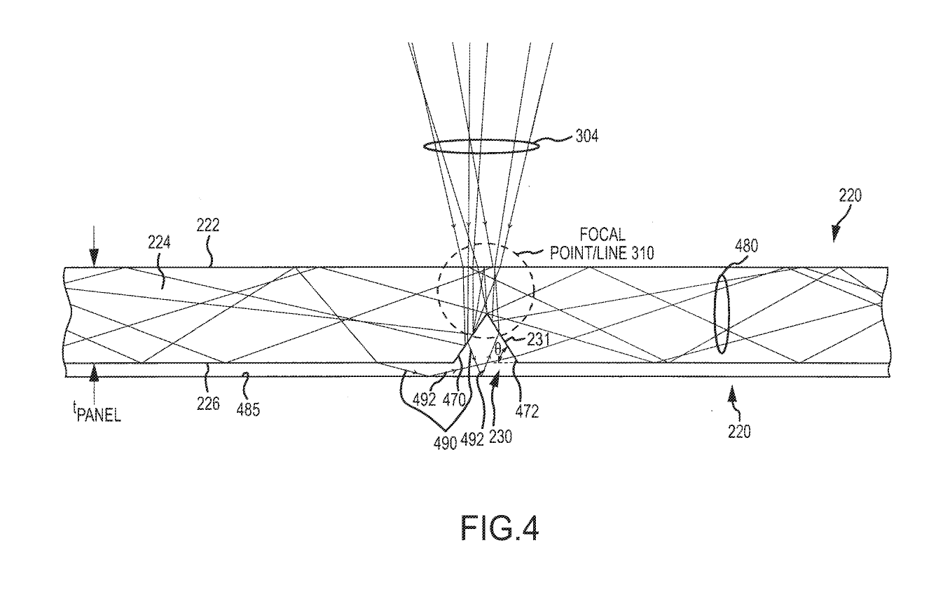

The system 200 also includes a concentration panel or light wafer 220 spaced apart from the lens array 210 by the height, H_{Array}, which is matched or tuned to be at or near the focal length of the lens 212 as shown in FIGS. 3 and 4. The concentration panel 220 includes a first or receiving (or front) surface 222 that receives light focused from each lens 212 and also includes a body 224 (or material thickness of a sheet) that may be formed of a thickness, t_{Panel}, e.g., less than about 0.25 inches in many cases where the sheet 220 is formed from glass or plastic. The panel or wafer 220 further includes a second or back surface 226 opposite the first or front surface 222. The back surface 226 includes a plurality of linear or elongated grooves or indentations extending along the length of the wafer or sheet 220 to define a number of ray splitters 230 in the body 224. In other words, material is removed from the body 224 on surface 226 to form ray splitter or beam deflection structures/surfaces on the inner portion/sides 231 of the back wall 226 that faces the first or front surface 222 (e.g., a triangular groove or valley or the like).

To collect any light trapped within the concentration panel 220, the concentration system 200 includes a collector 240, 241 at each end 232, 233 of the panel 220. The inward facing or deflection surfaces 231 of the ray splitters 230 direct or deflect the light focused from lenses 212 in both directions in this embodiment such that about half of the concentrated light exits the wafer 220 at end 232 into collector 240 while the other half of the light from lenses 212 is directed to collector 241. In practice, the collectors 240, 241 may be panels or strips of PV material (or PV devices such as solar cells or the like). In other cases, the collectors 240, 241 may be collector or absorber tubes carrying a working or transfer fluid such as water, air, oil, or nearly any other fluid desired for a thermal CSP system incorporating the concentration system 200.

FIG. 3 illustrates a ray tracing for the concentration system 200. Sunlight 302 is received on surface 214 of the lenses 212 of array 210. The lenses 212 act to transmit the focused light 304 from back or inner surface 216 toward the concentration panel or light wafer 220 and top/first surface 222. The lenses 212 typically all have the same or a similar focal length and the height, H_{Array}, of the lens array 210 is set (or tuned such as by an actuator moving the array 210) to match this focal length such that the focal point/line 310 of the lenses (such as shown for lens 212) is on the concentration panel 220. More specifically and preferably, the focal point 310 (or line since the lens 212 is a linear lens) is aligned with the panel 220 such, that the focal point/line 310 is on a portion of the surface 222 that causes the focused light 304 to strike a ray splitter 230 along all or most of its length in wafer or panel 220. The ray splitter 230 (or its surface 231) causes the light 304 to be directed into the body 224 and retained there by Tilt as shown with arrows 306, 307 to enter collectors 240, 241 at wafer ends/edges 232, 233.

This is shown more clearly in the close up view of the concentration panel 220 with the ray tracing shown in FIG. 4. As shown, the panel body 224 has a thickness, t_{Panel}, such as 0.125 (or less) to 0.25 inches or the like. The panel body 224 includes a ray splitter 230 in the form of a triangular groove in surface 226 with angled sidewalls 470, 472. The ray splitter 230 is formed by removing material from the body 224 to provide inner deflection surfaces 231 in body 224, and the ray splitters 230 are typically formed with sidewalls 470, 472 at an angle, θ, as measured from a plane extending out from surface 226 of about 30 to 60 degrees with 45 degree-angled sidewalls 470, 472 shown in FIG. 4 as one useful example.

In use, as shown in FIGS. 3 and 4, the focused light 304 may be focused by lens 212 at a focal point/line 310 that may coincide with the surface 222, a depth into the body 224 between the ray splitter 230 and the surface 222, and/or the surfaces 231 of the ray splitter 230 such as the upper portion of the triangular shape (e.g., the peak or apex of the triangle defined by walls 470, 472 or the upper quarter to half of the walls 470, 472 on surface 231). As shown, the light 304 travels into through surface 222 into body 224 and strikes surfaces 231 defined by walls 470, 472. A large percentage is trapped by TER within the body 224 as shown at 480 and travels toward one of the edges/ends of the wafer 220. Some light 490 may exit the body 224 of the wafer 220 in the ray splitter 230 or elsewhere, and, optionally, a reflector or mirror element with reflective/mirrored surface 485 may be provided to reflect the light 492 back into the wafer 220.

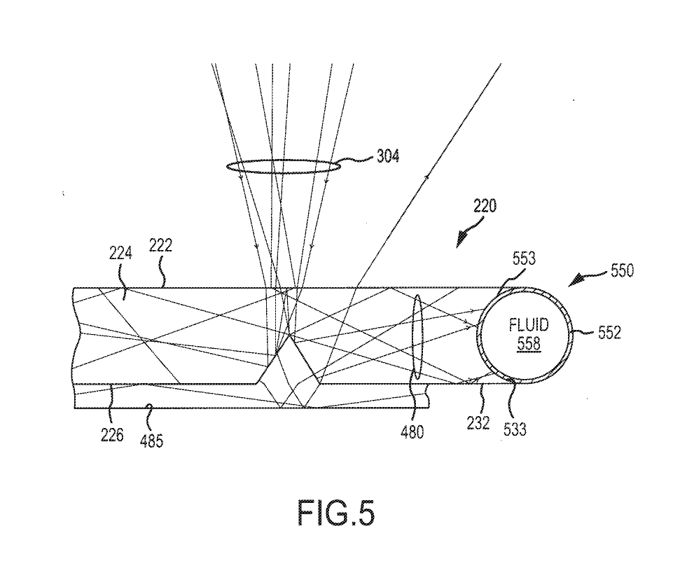

FIG. 5 illustrates an embodiment where a collector 550 is provided at the end 232 of the wafer 220 in the form of an absorber tube. The absorber tube 550 includes a cylindrical sidewall 552 defining an interior space or void for carrying a volume of working or transfer fluid 558 (such as air, water, or the like). The edge/end 232 is in abutting contact at surface 533 of body 224 with a portion of the outer surface 553 to direct light 480 collected from focused light 304 that strikes the ray splitters 230 and is retained within the body 224 by TIR. The sidewall 552 at least at surface 553 is transparent or substantially so such that fluid 558 collects the solar energy of light 480, and a reflector/mirror may be provided on an opposite portion of sidewall 552 to reflect back any light/energy not initially absorbed by fluid 558.

In some other preferred embodiments, one or more PV devices or panels/strips may be positioned on or near the sidewall 552 of the tube 550 opposite the edge/end 232 to receive and collect light 480 that is not absorbed (or used) by the fluid 558. In the same or other embodiments, the reflector/mirror element 485 may be replaced with one or more PV devices or panels/strips to receive/collect sunlight or rays 490 that are lost from the body 224 of the light wafer or concentration panel (e.g., light that is not trapped by TIR or the like). Further, PV devices or panels/strips may be used as the collector 240 and/or collector 241 in a PV-based CSP system or in a combination PV-thermal CSP system, as will be readily understood by those skilled in the solar power industry.

A number of assumptions were made in creating the ray tracings of FIGS. 3-5, and, also, a number of characteristics of this embodiment of the concentration assembly 200 were determined. The ray collection fraction was 0.35, the intensity fraction of rays collection was 0.79, the net efficiency was 0.27, the concentration ratio (physical) was 26.44, the concentration ratio (effective) was 7.18, the temperature of the collector was about 880° C., the solar constant was 1000 W/m2, the emissivity was 1.00, and the mirror reflectivity was 0.95. With these calculations performed by the inventors, it can be seen that the concentration assembly 200 effectively uses a combination of linear lenses and ray splitters in a concentration panel or light wafer to capture and concentrate light, which is then delivered to a collector.

With these particular examples in mind, it may be useful to again discuss a preferred embodiment of a concentration assembly, which may be considered a linear version, more generally. In this version, the lens array is made up of 1 to 10 or more linear lenses arranged in a side-by-side manner with their longitudinal axes parallel to each other. Each linear lens is typically identical (or substantially so) and may be a cylinder lens or a Fresnel lens (curved or flat). The lenses of the lens array focus sunlight or the Sun's rays down into a flat glass or plastic light wafer or concentration panel. In this panel, the rays enter the plastic or glass sheet via its top or receiving surface and travel to the back of the sheet to a reverse “V” shaped (prism shaped) ray splitter, with some embodiments providing one ray splitter per lens in the form of a linear groove or trough cut into the back side of the light wafer sheet. Each ray splitter may be V-shaped with angles of from approximately 40-50 degrees with most structures between 43 and 50 degrees.

In use, the surfaces of the ray splitter facing the lenses (and facing or proximate to the receiving or front surface of the concentration panel/sheet) are struck by the rays concentrated or focused by a matched or corresponding one of the linear lenses. In one embodiment, the rays are focused by the lens so that the focal point of the lens is some distance below the apex of the structure of the ray splitter (e.g., a 5 to 50 percent offset of the height of the triangular or V-shaped splitter). The rays focused by the lens enter the body of the light wafer or concentration sheet/panel at an angle that allows the rays to be deflected by the sides of the ray splitter to bounce within the glass or plastic of the planar light wafer/concentration panel. Stated differently, the rays glance off the structures/ray splitters without going through the structures using total internal reflection (TIR) and then the trapped (or loosely “split” rays) contained by TIR in the body continue down the glass or plastic light wafer or concentration sheet/panel. The rays may be directed one way or both ways by the ray splitter sidewalls, with higher efficiency levels and less rays escaping the device when rays are split into two groups and forced to go in both directions away from the ray splitter (e.g., about half of the focused light is directed toward each edge/end of the light wafer/concentration panel).

The focal lengths of the lenses may be very short using small lenses such as lenses that are each less than 0.25 inches in width (or across). In other embodiments, very large array heights may be acceptable and the lenses may be much wider such as up to about 8 feet or more in width with focal lengths of 16 feet or more. For most industrial applications, lenses about 8 to 10 inches in width may be appropriate with focal lengths of 12 to 20 inches. The glass or plastic sheet used to provide a light wafer or concentration panel (with ray splitters) may be up to several inches thick. For example, the lens array may include linear lenses that are about 8 inches wide, and it may be useful to use a light wafer with thicknesses of about 0.125 to 0.25 inches thick with such a lens array. The lenses of the lens array typically repeat every width of each lens, with no gaps between the lenses, focusing received sunlight into the body of the light wafer/concentration panel and onto the included/contained structures or ray splitters.

The lens array is held in place by a frame over the “ray splitter” and may be focused perfectly (or nearly so) with each lens focusing a line of light onto the linear upper surfaces of a corresponding one of the ray splitting structures. From above the light receiving surface of each ray splitter would be a long and very narrow rectangle (e.g., a rectangle that is 5 to 20 foot (or more) in length but less than an inch or two in height such as a fraction of an inch such that the focused light appears to be a line or strip below each lens of the lens array.

For desirable functioning of each concentration system, the system should track the Sun either in one axis or in two axes. One preferred method is to track the Sun in one axis. In this embodiment, the concentration assembly may be configured (as discussed with reference to FIG. 1) with the ability or functioning mechanisms such as computer-controlled actuators/motors to move the lens array up and down relative to the light wafer/concentration panel to adjust the focal length so that the focus may more readily accommodate the change in seasonal azimuth, as well as side-to-side slightly for better focus to the ray splitting structures. This can be done with servo motors, adjusting the lens above the glass or plastic body of the light wafer or concentration panel.

A disruptive aspect of the technology provided by the concentration systems is the really low cost and the simplicity of the devices used in each system. Additionally, the concentration systems provide the opportunity to create a device that allows several thousand Suns for concentrating light to photovoltaics (or PV devices), for thermal energy, or for both such systems/devices that may be used in a CSP system. Ray collection efficiencies up to 75 percent have been modeled by the inventors, and concentration ratios of more than 10,000 Suns are believed possible. Sheets or concentration panels may be linked together for great distances/surface area coverage.

The low cost is nothing more than “astounding” as the device can be made essentially out of two sheets of etched glass or plastic (the etching providing the ray splitters on the back or rear surface of the concentration panels) with one or two axis tracking systems. The device's ability to “link” to other sheets or panels accumulating energy to achieve very high concentration ratios in order to minimize the use of PV materials or generate heat is unprecedented. Panels can be linked to create enough heat to generate steam and/or to heat oil or glycol for thermal solar CSP systems. There are reasons to believe the described concentration systems will be useful for creating some of the least expensive but yet one of the most efficient solar thermal devices available to the solar power and renewable energy industry. In addition, the concentration systems described have the ability to concentrate rays/sunlight at over 10,000 times. While there is a physical limitation of the multiple of Suns possible due to ongoing ray loss in the splitter structures, the limitation is likely several thousand Suns or more.

The inventors believe the importance of the ability of this device to create meaningful heat from solar energy at a level over 1,000 suns in a linear device cannot be overstated. For instance, prior efforts have shown devices considered revolutionary, e.g., concentrators that use a series of angular steps and mirrors, that only produce about a 10 times multiple for Sun concentration. The described concentration systems represent a large step forward relative to such systems, and a glass collector used with such concentrators would be capable of producing heat of well over 3,000° C. by linking panels together and combining them unit-to-unit.

The linear lens systems or arrays accompanying the sheet lens splitters (or light wafers with built-in ray splitters) may be traditional cylinder lenses, flat linear lenses (prisms inside or outside), elliptical lenses, or curved Fresnel lenses. The lenses may be very small (e.g., less than ⅛-inch wide each) or massive at over 8 feet across. Focal lengths may vary from less than about 0.125 inches to well over 10 feet. A more reasonable range of lenses would be about 1 inch wide to about 24 inches wide, allowing the overall device to have a low profile.

The lens system can be one axis tracking or two axis tracking system, though one axis is preferable due to cost and the ease of linking the panels in two directions. In this embodiment, the lenses would generally run parallel to the east and west directions, but it need not necessarily be in that orientation due to ancillary tracking. In embodiments using ancillary tracking, the lens system can move vertically and horizontally for adjustment (or conversely, the ray splitter sheet can move) or both the ray splitter and the lens system can move. In addition to the device following the Sun in the form of linked panels much like a “trough” system, this concentrator can tilt and track in a similar matter but can also adjust in two directions to allow an accurate focus to the ray splitters so that the focal point of each lens hits a splitter perfectly (or in a desired manner) to be able to split the rays into two groups or to direct the rays in one direction. In either case, the rays are “trapped” inside the glass or plastic body of the light wafer or concentration panel at correct or useful angles for TIR, thereby maintaining the rays in the light wafer or concentration panel until they eventually exit a side/edge/end of the glass or plastic wafer/panel to be harvested for PV collection and/or thermal solar collection.

It is important to note that in this type of tracking (basically subtle movements up and down or side to side of either the glass or plastic ray splitter (or wafer/panel/sheet with ray splitters) or the lens array or both) that in many cases, it is not necessary to “tilt” or follow the zenith of the Sun. The whole unit can remain stationary and appear not to move while making very subtle movements up and down and side to side of less than an inch or up to a few feet depending upon the size of the unit's lens system and the corresponding focal lengths. While the efficiencies may be less, this type of tracking will eliminate the need for spacing the devices for shadowing and provides a unique option for a tracking PV device as well as an industrial heat collector. This embodiment allows for a low profile and also for placement upon any roof or sloped surface. Such embodiments also facilitate subtle tracking and very good ray collection efficiencies of up to 60 percent or more. The cost for this type of tracking is also very low, as the movements necessary to adjust the focal length of the lens into the splitter is nominal. Therefore, the servos and gears (if even needed) are quite small.

At this point, it may be useful to again stress how the use of linear lenses such as linear Fresnel lenses arranged in a planar array that can be moved with a 2-axis tracking/positioning system facilitates that changing of the focal point(s) of each concentration system of a CSP system to suit seasonal locations of the Sun (and, in some cases, to first calibrate an installed assembly after fabrication/shipping). As the altitude of the Sun changes during the seasons, a one-axis tracking system that relies on lenses or mirrors that focus the light of the Sun on a receiver will not optimally concentrate the light on the receiver for the various angles of elevation.

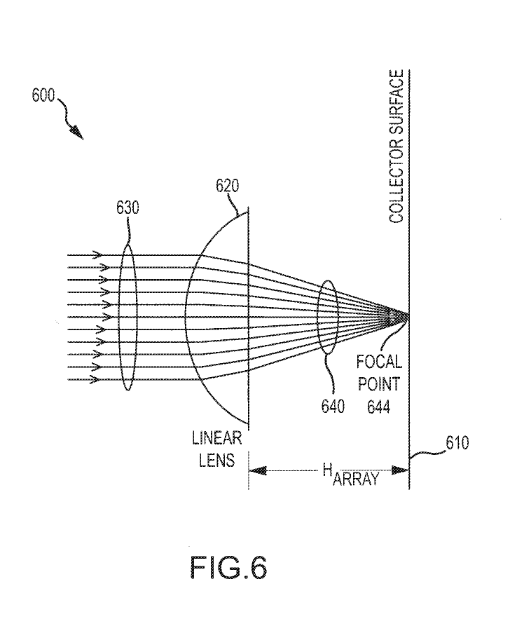

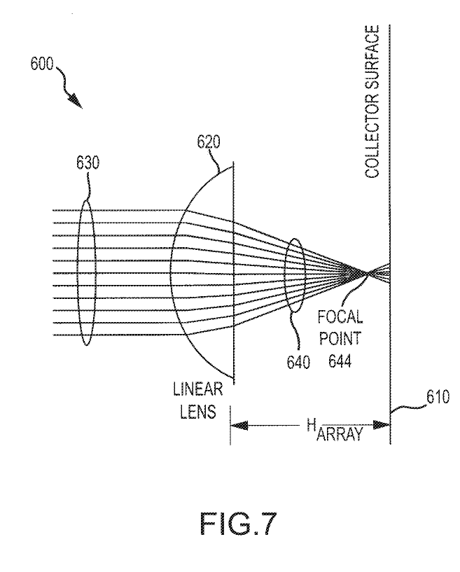

Such an issue can be seen through a quick review of FIGS. 6 and 7. FIG. 6 illustrates a portion of a concentrator assembly 600 during use to receive light 630 with one or more linear lenses 620 and focus light 640 onto a focal point 644. In FIG. 6, the height of the array, H_{Array}, is correct for the position of the Sun providing light 630 to have the focal point 644 coincide with the collector surface 610 and any edges/ends of light wafers that may be collocated on such surface 610. However, in FIG. 7 the same lens/surface separation, H_{Array}, results in the focal point 644 being spaced apart from the collector surface 610 (i.e., the Sun's seasonal position has caused the lens 620 to lose its focus onto the surface 610).

The cause of the change between operation of assembly 600 in FIGS. 6 and 7 may be because the path lengths after refraction or reflection change with the Sun's altitude angle and because only one-axis is presently being used in assembly 600 (day tracking). Hence, the plot of FIG. 6 shows the incoming rays 630 and spot patterns 644 at 27 degrees from the vertical along the axis of a cylindrical linear lens are compared to the incident rays at zero degrees incidence, and the assembly 600 in FIG. 6 achieves reasonable good focus onto the collector surface. However, the plot of FIG. 7 shows operation of the assembly 600 at a differing Sun position, and the incident rays are 27 degrees from the vertical in a direction perpendicular to the plane of the plot. Proper focus is not achieved as the focal point 644 is now spaced apart or is not coincident with collector surface 610. Spot diagrams of an array of linear lenses focusing on a cylinder collector 610 also indicate good focusing along the length of the cylinder (along the length of the linear lenses of a lens array) in the arrangement of FIG. 6. However, spot diagrams of the situation shown in FIG. 7 show that there is a spread of rays along a Y-axis (e.g., focal point 644 is not on the cylinder's surface), which is detrimental as some of the rays 640 will miss the collector 610 (and not be available to heat a transfer fluid (or strike PV material)). Embodiments of the invention described herein, though, address this problem by moving the lens array and its lenses (e.g., arched, linear Fresnel lenses) to an optimal position or distance, H_{Array}, from the concentration panel/sheet upper or light receiving surface (or its ray splitters in such panel/sheet) to suit the Sun's seasonal position to capture the maximum amount of light possible.

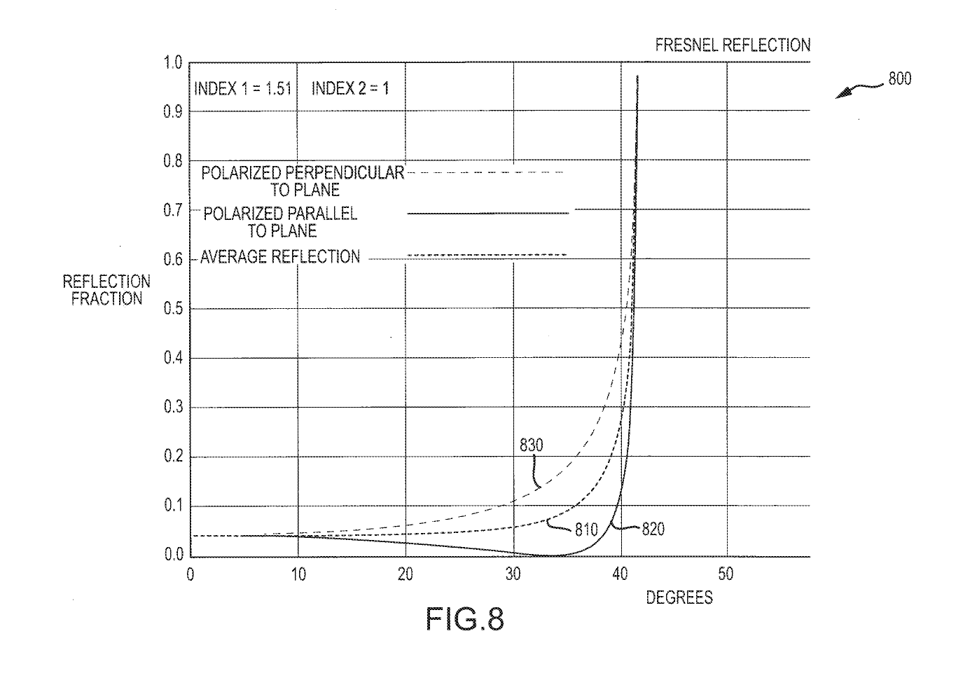

In order to contain the maximum number of rays possible in the light wafer/concentration panel (or sheet) of a concentration system (such as the one shown in FIG. 1), some considerations about total internal reflection (TIR) should to be taken into account. As will be understood by those skilled in the art, there is a dependence of the intensity of rays as a function of the angle of incidence when in a medium of higher refractive index than the surrounding medium. For example, FIG. 8 provides a plot 800 that was created to compare a fraction of reflection (Y-axis) to the angles of incidence of light (X-axis) within a material (such as a light wafer), e.g., for a material with an index of refraction of 1.51 when the surrounding index is 1.00 (air). The plot 800 includes lines indicative of average reflection 810, light polarized parallel to plane 820, and light polarized perpendicular to plane 830 to illustrate Fresnel reflections to illustrate total internal reflection (TIR). The plot 800 shows that when the angle of incidence is around 42 degrees, most of the energy of the ray is reflected (via TIR) or trapped within the material. Hence, for the planar optical wafers described herein, as long as the angle of incidence is greater than the critical angle, rays in the wafers will be contained in the wafer and directed on to an output end/edge of the wafer to be targeted onto a collector (or a shell rotating about an absorber tube in some embodiments).

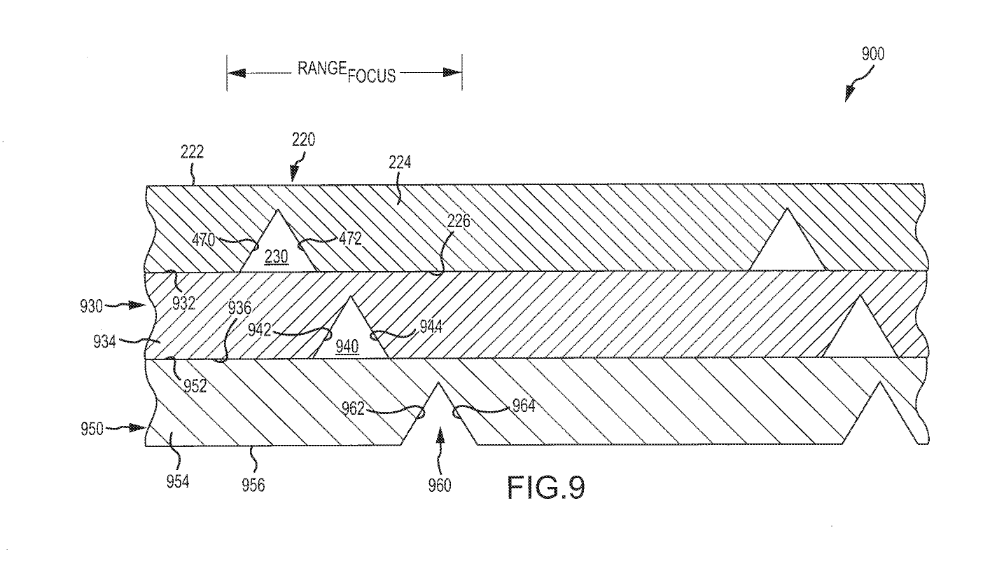

As an addition to the singular glass or plastic sheet with the ray splitter (and as discussed with to FIG. 9), there may be additional sheets with additional splitters below the primary sheet to capture and split rays that are off axis, so that the device is more forgiving and allowing a greater range of angles of entry to the light wafer or concentration panel. There may be several sheets with offset structures directly under one another, even to the point that the device requires no tracking whatsoever and may be a stationary device. Note that the more surfaces the rays penetrate and exit, the less efficient the device will be losing 5% at each juncture of transition.

The thickness of the sheets used for the wafers or concentration panels may vary to practice the invention. For example, a thickness in practice ranging from about 0.015 inches to about 3 inches in thickness may be useful for the optical wafers, which may take the form of bent sheets of low iron glass or the like. In some cases, several sheets may be bonded together (e.g., two to four or more sheets of ⅛-inch or other thickness glass, plastic, ceramic, or other material may be used). The adjoining wafers may be glued together with a polymer or epoxy, may be melted together, or joined in any way with materials that have a similar refractive index of the material used in the wafer material (e.g., glass, plastic, or the like). Generally, this refractive index will be between about 1.38 and about 1.95 (or average between about 1.5 and 1.6 which is the range for glass, plastic, or PMMA).

It may be desirable for the concentration system to be configured to account for changes in the Sun's position (e.g., during seasonal changes (or over the year) and/or during each day). One useful technique that can be used to make the device or concentration system more forgiving to varying entrant ray angles due to seasonal or zenith variations can be to include an array or assembly of light wafers or concentration panels. In other words, the concentration system may include two to ten or more of the optical wafers or concentration panels with integral or “built-in” ray splitters such that the ray splitters are staggered or positioned in a step-wise offset in each layer to cover a range of entrant angle or incidence angles for received sunlight. In this manner, the concentration system provides or includes additional ray splitters layered underneath the first or top layer ray splitters so that the rays or sunlight focal lengths from the focusing lenses are targeted in specific light wafers or concentration panels/sheets onto a matching or corresponding splitter based on (or to suit) the entrant or incidence angle of the incoming rays (e.g., based on the position of the Sun relative to the concentration system).

For example, two to ten or more ray splitter-containing sheets, wafers, or panels may be layered together in abutting fashion (or with small air gaps and/or adhesive layers) to accommodate virtually all incoming ray angles thus providing a non-moving, self correcting tracking device (e.g., eliminate the need for up and down movement of the lens array relative to the light wafers/concentration panels). However, some level of tracking and/or focusing/tuning may be desirable even in such stacked panel, concentration system, and, hence, this self-correcting/tracking concept can be used in conjunction with the ray splitters moving up and down and/or side to side (or the lens array moving up and down and/or side to side).

However, it is important to note that the rays or sunlight may lose energy moving through multiple ray splitters because of the losses of about five percent entering and exiting each of the mediums. In this case, the more efficient version of this embodiment of this device would be to use the upper ray splitters for the center rays (e.g., when the Sun is directly overhead or the like) and to use the lower units (second, third, fourth, and so on units) to accommodate the outside rays as these already have less energy. In general terms, however, utilizing more than one splitter can make the device more forgiving for ray entrant angles. With about three consecutive splitters, one can make the device angle acceptance about plus or minus more than 12 degrees without tracking (regular or ancillary).

FIG. 9 illustrates partial sectional view of an array or assembly 900 of light wafers or concentration panels arranged in a stacked but offset manner so as to stagger the ray splitter structures in each consecutive layer such that each layer is effective for capturing sunlight striking the array at differing entrant or incidence angles. In other words, a lens array providing two or more linear lenses may—without having to move the lens array (or wafer assembly 900) up and down to maintain a single focus configuration—be able to focus on the array 900 a range of focal points (as shown by Range_{Focus} in FIG. 9). The focal points of the lenses correspond with differing locations of the Sun (e.g., position in summer versus position in fall, spring, and/or winter).

As shown, the array 900 includes the light wafer or concentration panel 220 shown in FIG. 4 with its triangular (or inverse/upside down “V” shaped) ray splitters 230. Again, the sides 470, 472 of the ray splitter 230 may be at an angle as measured from a plane passing through the back surface 226 of 37 to 55 degrees such as about 43 to about 48 degrees in some cases. Hence, the angled sidewalls 470, 472 define an amount of material removed from body 224 and an air gap/space adjacent to the inner side of back or second surface 226 of the wafer or concentration panel that caused light passing through the body 224 to strike be deflected toward opposite edges/ends of the body 224 (or to be trapped via TIR in the wafer or panel 220).

However, the lenses of the lens array (not shown in FIG. 9 but described in detail elsewhere) may not be fully accurate or the focal point may move within the range, Range_{Focus}, due to movement of the Sun relative to a concentration system containing the assembly 900. To better capture sunlight focused from the lenses (without constant refocusing/tracking or to simply account for manufacturing/assembly tolerances), the assembly 900 includes a second light wafer or concentration panel 930 positioned “below” the first wafer/panel 220. The panel 930 may have an identical configuration as the panel 220 but have its ray splitters offset when viewed from above (from the direction of the lenses focusing on the assembly 900 and first receiving surface 222). In this way, the acceptable range, Range_{Focus}, for capturing focused sunlight is increased (e.g., doubles or at least significantly increased depending on the amount of offset or staggering utilized).

As shown, the wafer 930 includes a body 934 with a first or light receiving surface 932 abutting (or at least proximate to) the back or second surface 226 of the first or top wafer 220. In some cases, the two sheets 220, 930 are bonded together with a substantially light-transparent adhesive or other coupling techniques may be used to maintain a desired alignment of the splitters 230, 940. The body 934 includes a second or back surface 936, and in this surface 936, two or more ray splitters 940 are cut by providing angled sidewalls 942, 944 defining an upside down V or triangular cross section air gap. The ray splitter 940 may be completed offset from ray splitter 230 or some overlap may be allowed/provided (e.g., the lower half or some other portion of the ray splitter 940 may overlap with the lower half or some other portion of the ray splitter 230) when light is preferably focused on an upper half or other portion of each ray splitter 230, 940.

The assembly 900 may include 2 to 10 or more layers, and the assembly 900 is shown to include a third light wafer or concentration panel 950 that is configured identically to the wafers 220, 930 but offset spatially. Specifically, the wafer 950 includes a body with a thickness defined by a first or top surface 952 abutting (or proximate to) back or second surface 936 of second/middle wafer 930 and by a second or back surface 956. Both surfaces 952, 956 are planar and the back surface 956 includes grooves or recessed surfaces extending along its length providing ray splitters 960. The ray splitter 960 is provides an inverse V or triangular shaped air gap that extends upward a distance into the body 954 of wafer as defined by the angled sidewalls 962, 964 (e.g., angled inward 40 to 55 degrees as measured from a plane extending out from surface 956).

Again, the ray splitter 960 may be spatially offset from the second or middle ray splitter 940 of wafer 930 to further expand the focal width or range, Range_{Focus}, of a lens in a lens array positioned above the assembly 900. The amount of the offset may vary to practice the assembly 900, but, as discussed above, it may be a full offset (or even more) such that the full inner surfaces 956 of the ray splitter 960 provided by sidewalls 962, 964 is visible or exposed to a paired or matched lens. In other cases, though, the lateral offset may be partial such that the lower or bottom half (or some other portion) of the sidewall 962 is hidden from the lens. In this way, the lens matched to the ray splitters 230, 940, 960 may be able to focus on the full area of the ray splitters 230, 940, 960 defined by sidewalls 470, 472, 942, 944, 962, 964 or some smaller fraction may be available to the lens to better capture/direct focused light within the bodies 224, 934, 954 of the wafers 220, 930, 950.

Generally speaking, the splitter-containing sheets/panels/wafers may have thicknesses that correspond to the focal point of the lenses of the lens array. The accuracy of the tracking and the ability of the lens array to properly focus sunlight are combined with the tracking devices to cause the focused light to hit or strike the splitters in the optical wafers or concentration panels so that the ray loss is minimized (or at least substantially reduced). In general, a linear lens about 8-inches wide repeating hundreds of times can utilize a ⅛-inch thick light wafer or concentration panel (e.g., a glass sheet or panel with a plurality of ray splitters provided in a back surface).

To show how dynamic this concentration device can be, a 36-foot long multi-panel piece would have the following concentration ratio: 36 feet×12 inches=432 inches in length; 432 inches×8 inches in width=3456 square inches/2(Eff=0.75)=1,296×at both edges of the glass. This can be a continual concentration ratio the length of the glass on two sides (thousands of feet).

Regarding costs, this concentrator is literally two sheets of glass (or one glass and one polymer, or two polymers, or two glasses). One with a lens structure such as a flat Fresnel lens (repeating) and then another sheet spaced underneath held together by frames at the right distance to accommodate the focal length of the device. Essentially, this is just two sheets of material with air between them that provide a highly efficient concentrator capable of several thousand degrees of heat generation.

The lens array may utilize lens other than linear flat or arched lenses. In such embodiments, for example, a circular, spherical, or other lens may be used in the array to focus to a point instead of a line, and the ray-splitters may be cones or pyramidal in shape, with a cone representing one preferred shape. The rays are then sent out to the edges of the circular, oval, or other shape of the light wafer or concentration panel having the cone, pyramid, or other shaped dimples or recessed portions on its back surface and collected as they exit the medium. Note, these lenses may be round, but repeating on a square or rectangular medium so that the rays combine in each lens system and also continue to link from all angles. In this embodiment, since the rays do not exit two edges, but rather all edges of the light wafer/concentration panel, the PV or heat collection is assumed to be at all of the edges of the glass or plastic sheet/plate. These combinations of a lens array and light wafer with ray splitters may be repeated throughout the device, which may be linked for hundreds or thousands of feet. In this embodiment, the concentrator may be well suited for PV concentration.

In some embodiments, PV collection and thermal collection may occur at the same time with one side or edge of the glass/plastic/ceramic wafer or concentration panel accommodating PV collection while the other side is collecting strictly heat for thermal solar application (e.g., about half the rays are directed toward a PV collector while the other rays are directed by ray splitters toward a thermal collector). In addition, there may be strips put virtually anywhere in the glass, plastic, or ceramic wafer or panel (or its body) to selectively remove or absorb just the rays that happen to bounce to that point. For example, the back surface of the concentration panel may include PV devices interposed between and/or adjacent the ray splitters to absorb rays that may escape from the body of the wafer or panel.

In some embodiments, the concentration system may be configured as an inexpensive PV concentrator with all collectors being PV devices/assemblies. PV materials can be engineered for various ideal concentration ratios, up to over about 1000 Suns concentration. In nearly all cases, the efficiency of PV materials improves with greater concentration. The PV strips may be placed anywhere on the top or the bottom of the glass or ray splitting wafer, in any position on the top or the bottom of the glass/plastic wafer, or at the edges of the glass/plastic wafer. In one embodiment, one side or edge of the glass/plastic wafer may be a PV collector, while the other may be a thermal collector as discussed above. In another embodiment, in a rectangle linear splitter, not all of the incoming rays will make it to the ends of the collector for thermal collection, so the non-collecting sides (lengthwise) may be PV strips on the edges of the glass or mirrors to reflect the errant rays back to the collectors.

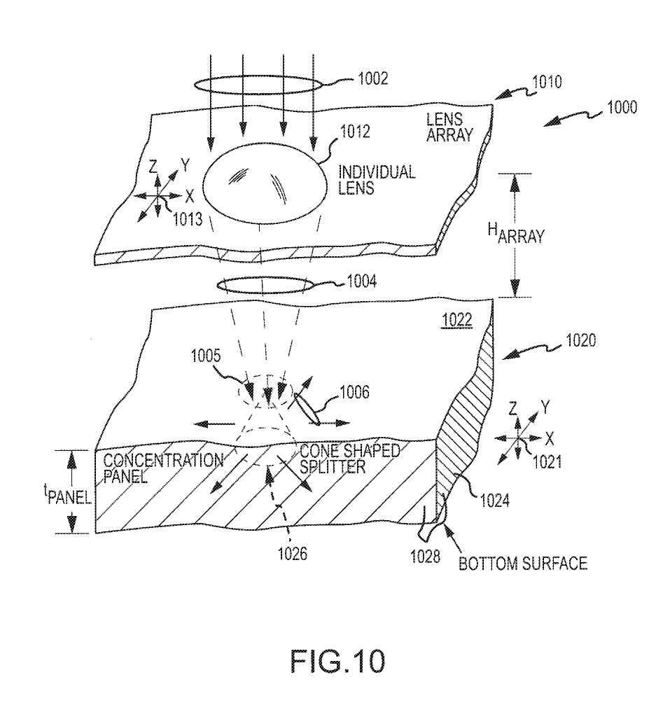

As mentioned above, concentration system embodiments may use a wide variety of lens shape and configurations as well as paired ray splitter shapes and configurations to concentrate sunlight. FIG. 10 illustrates a concentration system 1000 with a partial perspective (and schematic) view showing used of non-linear lenses that are paired with non-linear ray splitters. Specifically, the concentration system 1000 includes a lens array 1010 that is spaced apart a distance (e.g., the focal length of the lens 1012), H_{Array}, from a concentration panel or light wafer 1020. The lens array 1010 includes a plurality of lenses with a single lens 1012 shown that receives sunlight 1002 and focuses the light 1004 onto a focal point 1005 on or in the concentration panel 1020. The lens array 1010 may be configured such that the individual lens 1012 may be tilted individually to provide tracking of the sunlight 1002 (or the position of the Sun providing light 1002) as is shown with arrows 1013 indicating movement of each lens 1012 in array 1010 in up to three directions to focus light 1004 properly on concentration panel 1022.

Particularly, the concentration panel 1020 may take the form of a sheet or panel of glass, plastic, or ceramic that is light transmissive (e.g., substantially transparent to sunlight 1002). The panel 1020 includes a first or top light receiving surface 1022 that may be relatively smooth and/or planar to pass the received, focused light 1004 from the lens 1012 into the body or material of the sheet 1020 (which may have a thickness, t_{Panel}, of up to 0.5 inches or more). The lens 1012 is non-linear in this embodiment of the system 1000 and the concentration panel 1020 includes a non-linear ray splitter 1026 in its second or back surface 1024 (opposite the receiving surface 1022). The ray splitter 1026 is shown to be formed by removing a volume of material from the body of sheet 1020 to form a recessed surface or dimple having the shape of a cone extending with its point or apex toward the light receiving surface 1022 (such as with a sidewall defining a 37 to 50 degree cone with 45 to 48 degree cones being useful in many applications).

The surface 1024 corresponding to the sidewalls of the cone-shaped ray splitter 1026 receive the light 1004 that is focused upon it by the lens 1012 and redirect or split this light 1006 into a plurality of directions. The split rays or redirect rays 1006 may go in all directions from the cone-shaped ray splitter 1026 and toward all edges 1028 of the concentration panel 1020. Hence, solar collectors in the form of thermal collectors (e.g., tubes/pipes carrying transfer/working fluid) and/or PV collectors may be positioned at all or a subset of such edges 1024 to collect the concentrated energy 1004, 1006 from lens array 1010.

To provide proper focusing and/or tracking of the Sun's movement (seasonal and/or daily movements/positions), the concentration system 1000 may be configured such that the panel may be moved laterally or horizontally (e.g., in a plane parallel to the lens array 1010) in the X and Y directions and/or may be moved vertically (e.g., transverse (or even orthogonal to the lens array 1010) in the Y direction as is shown with arrows 1021. As discussed above for triangular linear splitters, it may be useful to have the lens 1012 focus onto the upper portion of the cone-shaped splitter 1026 to better capture the light 1006 within the body of the panel 1020 with TIR.

Only one lens 1012 and one corresponding or paired ray splitter is shown in FIG. 10, but it will be understood that the concentration system 1000 would include many more lenses and splitters to feed concentrated light to solar collectors (e.g., hundreds to thousands of such lens/splitter pairs). For example, the system 100 may be modified to include the concentration system 1000 of FIG. 10 in place of the system 110 with a lens array 1010 with hundreds to thousands of the lenses 1012 each focusing light into the concentration panel 1020 and onto a like number of cone-shaped ray splitters 1026.

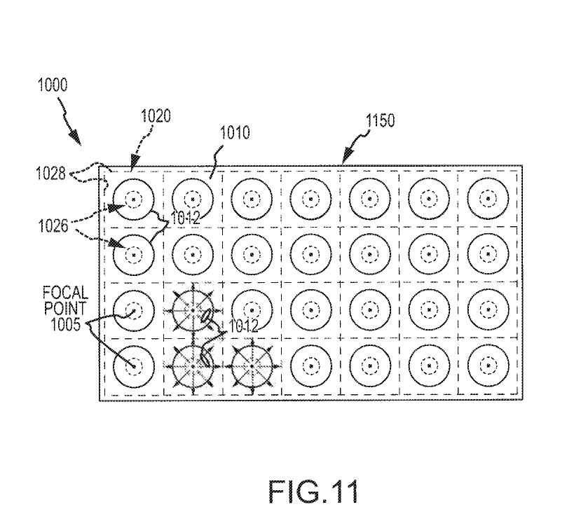

For example, FIG. 11 shows a top view of the concentration system 1000 (or a CSP system) indicating the lens array 1010 includes 28 individual lenses 1012. The lenses 1012 may be individually pivotal to track the position of the Sun in some embodiments of the system 1000. Each lens 1012 provides point focus rather than along a line as in prior systems described herein. As shown, each lens 1012 has a focus point 1005 that preferably coincides with a position (X-Y and, in some cases, Z position relative to the lens 1012) of ray splitter 1026 in a spaced apart concentration panel 1020. The ray splitters 1026 split or redirect the rays in the focused light at point 1005 causing the rays 1006 to disperse in all directions (360 degrees spread about the cone sidewalls). The light 1006 is trapped (at least partially) in the body of the concentration panel 1020 such that it travels to all edges 1028. A collector 1150 is positioned about the periphery of the concentration panel 1020 to collect the concentrated light 1006 from the splitters 1026.

The inventors created and utilized a number of ray tracing programs to facilitate their design of the collector assemblies described herein as well as using such programs as a proof of concept. To facilitate others skilled in the art in achieving the desirable results obtained by the inventors, the inventors are providing portions of the ray tracing routine source codes for a linear Fresnel lens-based embodiment. Mainly, the Fresnel lenses are designed automatically by the code using the index of refraction of the lens material as well desired focal lengths and the widths of lenses as input to the code. The light wafers are then drawn on the computer screen and adjusted in orientation (curvature/bending) by a designer to eliminate loss of rays at the greatest curvatures. Collection efficiencies and estimated temperatures are also calculated by the code. It will be seen by a study of the code that the code is, in part, a non-sequential ray trace program, e.g., the rays are followed wherever the geometry takes them.

As an example, the routine that finds the intersection of a ray with the wafer walls is given:

```
Sub Intersect_Mouse_Or_Computer_Wafer(i, j, xs, ys, zs, e1x, e1y, e1z, xi, yi, zi, enx, eny,
enz, surfaceprevious, surfacemousewafer, contact, intmousewaferflag)
‘intersect mouse or computer generated wafers
‘inputs
‘i=wafer kind, j=structure # of the kind of wafer
‘xs,ys,zs starting point of ray.
‘e1x,e1y,e1z, direction cosines of ray
‘outputs
‘xi,yi,zi intersection point
‘enx,eny,enz surface normal at intersection point.
‘intwaferflag=true if successful intersection
‘surfacemousewafer mainly sent to ray trace for debugging
Dim intx, inty, intflag As Boolean
Dim surf1, surf2 As String
Dim k, n, ntype As Integer
Dim xp, yp, zp, x0, y0, z0, r, gx, gy, gz As Double
Dim s1, tol1, tol2, tol3, temp, enxtemp, enytemp, enztemp, xitemp, yitemp, zitemp As
Double
Dim temp1, temp2 As Double
intmousewaferflag = False
temp = 10 \hat{ } 10
temp1 = 10 \hat{ } 9
temp2 = 10 \hat{ } 8
tol1 = 0.0001 ‘window of intersection tolerance
tol2 = 0.00001 ‘eliminate starting point self intersection
tol3 = 0.001 ‘nearness limit to decide if next surface is in contact
surfacemousewafer = “ ”
surf1 = “ ”
surf2 = “ ”
‘straight parts of wafers
For i = 1 To NumberStructures
  For j = 1 To 10
    If UseStructure(i, j) = True Then ‘need to keep this loop here when all wafers
compared.
    For n = 1 To (NumberLast(i, j) − 1)
      ‘If n > 12000 Then
      ‘ Beep
      ‘ MsgBox (“n>12000”)
      ‘ End If
      If MType(i, j, n) <> “E” Then ‘note, this means we do not intersect a segment
starting at an E going to the next point.
        xp = XM(i, j, n)
        yp = YM(i, j, n)
        zp = 0#
        s1 = Sqr((XM(i, j, n) − XM(i, j, (n + 1))) \hat{ } 2 + (YM(i, j, n) − YM(i, j, (n + 1))) \hat{ }
2)
        If s1 = 0# Then ‘point not line
        GoTo IMW50
        End If
        eny = (XM(i, j, n) − XM(i, j, (n + 1))) / s1
        enx = −(YM(i, j, n) − YM(i, j, (n + 1))) / s1
        enz = 0#
      intx = False
      inty = False
      Call intplane(xs, ys, zs, e1x, e1y, e1z, xp, yp, zp, enx, eny, enz, xi, yi, zi,
intflag)
      If intflag = True Then
        If xi >= (XM(i, j, n) − tol1) And xi <= (XM(i, j, (n + 1)) + tol1) Then
          intx = True
        End If
        If xi <= (XM(i, j, n) + tol1) And xi >= (XM(i, j, (n + 1)) − tol1) Then
          intx = True
        End If
        If yi >= (YM(i, j, n) − tol1) And yi <= (YM(i, j, (n + 1)) + tol1) Then
          inty = True
        End If
        If yi <= (YM(i, j, n) + tol1) And yi >= (YM(i, j, (n + 1)) − tol1) Then
          inty = True
        End If
      End If
      If intx = True And inty = True Then
        s1 = Sqr((xi − xs) \hat{ } 2 + (yi − ys) \hat{ } 2 + (zi − zs) \hat{ } 2)
        If s1 < (temp + tol3) And s1 > tol2 Then ‘allow two different surfaces that
might be in contact to enter in here
          temp = s1
          temp2 = temp1
          temp1 = s1
          surf2 = surf1
          surf1 = MType(i, j, n)
          xitemp = xi
          yitemp = yi
          zitemp = zi
          enxtemp = enx
          enytemp = eny
          enztemp = enz
          surfacemousewafer = MType(i, j, n)
          intmousewaferflag = True
        End If
        End If
      End If
IMW50:
    Next n
  End If
  Next j
Next i
If intmousewaferflag = True Then
  If Abs(Abs(temp1) − Abs(temp2)) < tol3 Then
    contact = True
    Else
    contact = False
  End If
  If contact = True Then ‘?????????????????????????????
    If surf1 < > surfaceprevious Then
    surfacemousewafer = surf1
    Else
    surfacemousewafer = surf2
    End If
  End If
  xi = xitemp
  yi = yitemp
  zi = zitemp
  enx = enxtemp
  eny = enytemp
  enz = enztemp
  ‘If surfaceprevious = surfacemousewafer Then ‘if there was a gap the previous surface is
bounded by air
  ‘ surfacemousewafer = “Air”
  ‘End If
End If
End Sub
The subroutine that is used to trace the Fresnel lenses is:
Sub Intersect_Linear_Fresnel(i, xs, ys, zs, e1x, e1y, e1z, xi, yi, zi, enx, eny, enz,
intfresnelflag)
‘i=number of fresnel, xs,ys,zs = starting point of ray, e1x,e1y,e1z = direction cosines of ray
‘xi,yi,zi = intersection point of ray with fresnel, enx,eny,enz = direction cosine of normal at
intersection
‘intfresnelflag=true if intersection found.
Dim intflag, intx, inty As Boolean
Dim j As Integer
Dim s1, tol1, smallestdistance As Double
Dim ex, ey, ez, xp, yp, zp As Double
Dim enxsave, enysave, enzsave, xisave, yisave, zisave As Double
tol1 = 0.0001 * FresnelLensPitch(i)
smallestdistance = 10 \hat{ } 10
intfresnelflag = False
‘search across fresnel
For j = NLenticulesLeft(i) To NlenticulesRight(i)
  ‘get slope of facet
  s1 = Sqr((X2Fresnel(i, j) − X1Fresnel(i, j)) \hat{ } 2 + (Y2Fresnel(i, j) − Y1Fresnel(i, j)) \hat{ } 2)
  If s1 < > 0 Then
    ex = (X2Fresnel(i, j) − X1Fresnel(i, j)) / s1
    ey = (Y2Fresnel(i, j) − Y1Fresnel(i, j)) / s1
    enx = −ey
    eny = ex
    enz = 0#
    xp = X1Fresnel(i, j)
    yp = Y1Fresnel(i, j)
    zp = 0#
    Call intplane(xs, ys, zs, e1x, e1y, e1z, xp, yp, zp, enx, eny, enz, xi, yi, zi, intflag)
    If intflag = True Then
    intx = False
    inty = False
    If xi >= (X1Fresnel(i, j) − tol1) And xi < X2Fresnel(i, j) Then ‘check for intersection
in facet
      intx = True
    End If
    If xi <= X1Fresnel(i, j) And xi > (X2Fresnel(i, j) − tol1) Then
      intx = True
    End If
    If yi >= (Y1Fresnel(i, j) − tol1) And yi < Y2Fresnel(i, j) Then
      inty = True
    End If
    If yi <= Y1Fresnel(i, j) And yi > (Y2Fresnel(i, j) − tol1) Then
      inty = True
    End If
    If intx = True And inty = True Then
      s1 = Sqr((xi − xs) \hat{ } 2 + (yi − ys) \hat{ } 2 + (zi − zs) \hat{ } 2)
      If s1 < smallestdistance Then
      smallestdistance = s1
      xisave = xi
      yisave = yi
      zisave = zi
      enxsave = enx
      enysave = eny
      enzsave = enz
      intfresnelflag = True
      End If
    End If
    End If
  End If ‘s1
Next j
xi = xisave
yi = yisave
zi = zisave
enx = enxsave
eny = enysave
enz = enzsave
End Sub
```

We claim:

1. A concentration system for supplying concentrated solar energy, comprising:
a lens array comprising at least one linear lens extending a length of the lens array and focusing light received on an outer surface onto a focal point; and
a light wafer with a substantially planar body formed of a thickness of a light transmissive material, wherein the body includes a top surface facing the lens array and receiving the focused light from at least one the linear lens and a bottom surface opposite the top surface and wherein the light wafer comprises at least one ray splitter directing at least a portion of the received focused light into the body, whereby at least a portion of the directed light from the ray splitter is trapped in the body by total internal reflection.

2. The system of claim 1, wherein the at least one ray splitter is positioned proximate to the focal point of the at least one linear lens.

3. The system of claim 1, wherein the at least one ray splitter comprises a linear groove extending along a length of the body on the bottom surface, whereby an air gap is defined in the body opposite the top surface.

4. The system of claim 3, wherein the linear groove is defined by a pair of sidewalls each extending at an angle from the bottom surface to meet at an apex, whereby the air gap has a triangular cross sectional shape.

5. The system of claim 4, wherein the angle is selected from the range of 37 to 55 degrees.

6. The system of claim 5, wherein the angle is selected from the range of about 45 to about 48 degrees.

7. The system of claim 5, wherein the portion of the directed light is split into two sets of rays with a first set directed toward a first edge of the light wafer body and a second set directed toward a second edge of the light wafer body.

8. The system of claim 7, wherein a first collector is positioned at the first edge to receive at least a portion of the first set of rays and a second collector is positioned at the second edge to receive at least a portion of the second set of rays and wherein the first and second collectors each comprises a thermal collector, a photovoltaic collector, or a combination thermal and photovoltaic collector.

9. The system of claim 8, wherein the lens array includes at a number of the linear lenses and the light wafer includes a like number of the ray splitters aligned with the linear lenses to received focused light from the lens array.

10. The system of claim 9, wherein the system has a concentration ratio of at least about 20 Suns.

11. The system of claim 1, wherein the light wafer further comprises a mirror element with a reflective surface facing the bottom surface to reflect a portion of the focused light escaping the body back into the body.

12. The system of claim 1, further including at least one photovoltaic collector element proximate the bottom surface to receive a portion of the focused light escaping the body.

13. The system of claim 1, wherein the at least one linear lens comprises a linear Fresnel lens.

14. The system of claim 1, wherein the concentrator assembly includes an array positioning mechanism providing two-axis tracking of the lens array including tracking a position of the Sun during daytime hours and periodically adjusting the lens array height based on the Sun's azimuth to match a focal length of the linear lenses to the array height.

15. A concentrated solar power system, comprising:
a concentration panel comprising a sheet of light transmissive material with a first surface for receiving sunlight and an opposite second surface, the second surface including a plurality of spaced apart recessed surfaces defining ray splitters in the sheet;
at least one solar collector positioned proximate an edge of the sheet of the concentration panel; and
a lens array comprising a plurality of lenses focusing received sunlight onto a paired one of the ray splitters in the sheet of the concentration panel, wherein the ray splitters direct at least a fraction of the focused sunlight into the material of the sheet where it is trapped by total internal reflection and toward the edge for collection by the solar collector.

16. The system of claim 15, further including an array positioning assembly operating to match a height of the lens array relative to the concentration panel to a seasonal azimuth for the Sun such that a focal point of each of the lenses is proximate a portion of the paired one of the ray splitters.

17. The system of claim 15, wherein each of the lenses of the array is one of a linear Fresnel lens, a radius lens, a round lens, a round Fresnel lens, and a rectangular lens and the light transmissive material used to form the sheet is a glass, a plastic, or a ceramic material.

18. The system of claim 15, wherein each of the lenses is a substantially identical, linear lens and wherein the ray splitters are elongated grooves in the second surface parallel to the longitudinal axes of the linear lenses and with a triangular cross section defined by a pair of sidewalls at an angle of at least about 37 degrees relative to a plane containing the second surface.

19. The system of claim 15, wherein the concentration panel further comprises a second sheet of light transmissive material with a light receiving surface facing and proximate to the second surface of the sheet of light transmissive material, wherein the second sheet includes a plurality of recessed surfaces defining ray splitters in the sheet, and wherein the ray splitters of the second sheet are laterally offset from the ray splitters of the sheet such that a portion of the focused sunlight passes through the sheet without striking the ray splitters of the sheet to strike the ray splitters of the second sheet to be directed toward an edge of the second sheet.

20. A concentrator for a solar power system, comprising:
a lens array comprising a plurality of linear lenses each focusing received light onto a focal point a distance apart from the lens array;
a light wafer with a body of material that is substantially transparent to light, the body having a planar first surface facing the lens array to receive the focused light and having a second surface opposite the first surface; and
a plurality of linear grooves with triangular cross sections in the second surface, each of the linear grooves being positioned proximate to one of the focal points of the linear lenses and arranged with a longitudinal axis parallel to the linear lenses.

21. The concentrator of claim 20, wherein the triangular cross sections are each defined by two sidewalls at angles of at least about 37 degrees measured from a plane extending through the second surface of the light wafer body, whereby at least a portion of the focused light striking the second surface of the light wafer body at one of the sidewalls is trapped within the body via total internal reflection and travels to an edge of the light wafer body for collection.
